(19) United States
(12) Patent Application Publication
(10) Pub. No.: US 2017/0371990 A1
(43) Pub. Date: Dec. 28, 2017

(54) MODEL-BASED CALIBRATION OF AN ALL-DIGITAL PHASE LOCKED LOOP

(71) Applicant: QUALCOMM Incorporated, San Diego, CA (US)

(72) Inventors: Magnus Olov WIKLUND, San Jose, CA (US); Emanuele LOPELLI, Laguna Niguel, CA (US); Charles WANG, Irvine, CA (US)

(21) Appl. No.: 15/192,278

(22) Filed: Jun. 24, 2016

(51) Int. Cl. G06F 17/50; H04W 88/02; H03L 7/093; H03L 7/099

(52) U.S. Cl. CPC G06F 17/5036; H03L 7/0991; H04W 88/02; H03L 7/093; H03L 2207/50; H03L 2207/12

(57) ABSTRACT

A method of calibrating an All-Digital Phase Locked Loop (ADPLL) includes obtaining a model of the ADPLL and applying an input signal to both the ADPLL and to the model. The ADPLL generates an actual output of the ADPLL, while the model generates a model output. An error between the actual output of the ADPLL and the model output is then sensed. The method also includes generating a calibration value based on the error between the actual output of the ADPLL and the model output, and adjusting a feedforward gain of the ADPLL based on the calibration value.

### FIELD OF DISCLOSURE

This disclosure relates generally to electronic circuits, and in particular, but not exclusively to the calibration of an All-Digital Phase Locked Loop (ADPLL).

### BACKGROUND

Phase-locked loops are used in many applications, including use in local oscillators of wireless transceivers (i.e., receivers and/or transmitters). In certain applications, such phase-locked loops are implemented with analog circuitry. However, as the operating speeds of digital circuits increase, it is becoming more feasible to implement at least portions of a phase-locked loop for traditionally analog applications using digital building blocks. These phase-locked loops are often referred to as All-Digital Phase Locked Loops (ADPLLs).

In operation, an ADPLL may be configured to receive a frequency signal (e.g., FREQ) that is representative of a desired output frequency of the ADPLL. When the ADPLL is locked, the phase, frequency, or both, of an output of the ADPLL is locked relative to the frequency signal. In certain wireless transceivers, the reference clock signal may be generated by a baseband processor, or the like.

In some applications, a modulator may be used with the ADPLL to produce an output with a variety of frequencies. The modulator may be used in some instances to enable finer tuning of the output frequency of the ADPLL, or in the case of a wireless transceiver, enable the transceiver to perform frequency modulation of digital data.

Modulation of an ADPLL relies on a calibrated feedforward path in order to enable fast modulation rates, while a slower feedback path of the ADPLL ensures accurate settling of the modulation. However, calibration of the feedforward path of the ADPLL may be time consuming, complicated, and error prone. For example, a transceiver for use in wireless communications may generate numerous frequencies due to the large number of communication channels, where each operating frequency may require a separate calibration. Furthermore, certain conventional ADPLLs may drift out of calibration during operation with temperature or other process-related conditional changes.

### SUMMARY

The following presents a simplified summary relating to one or more aspects and/or embodiments associated with the mechanisms disclosed herein for the model-based calibration of an All-Digital Phase Locked Loop (ADPLL). As such, the following summary should not be considered an extensive overview relating to all contemplated aspects and/or embodiments, nor should the following summary be regarded to identify key or critical elements relating to all contemplated aspects and/or embodiments or to delineate the scope associated with any particular aspect and/or embodiment. Accordingly, the following summary presents certain concepts relating to one or more aspects and/or embodiments relating to the mechanisms disclosed herein to calibrate an ADPLL in a simplified form to precede the detailed description presented below.

According to one aspect, a method of calibrating an All-Digital Phase Locked Loop (ADPLL) includes obtaining a model of the ADPLL and applying an input signal to both the ADPLL and to the model. The ADPLL generates an actual output of the ADPLL, while the model generates a model output. An error between the actual output of the ADPLL and the model output is then sensed. The method also includes generating a calibration value based on the error between the actual output of the ADPLL and the model output, and adjusting a feedforward gain of the ADPLL based on the calibration value.

According to another aspect, an apparatus includes an All-Digital Phase Locked Loop (ADPLL), a model of the ADPLL, and a calibration value generator. The ADPLL is configured to generate an actual output of the ADPLL in response to an input signal and the model is configured to generate a model output in response to the input signal. The calibration value generator is coupled to the model and to the ADPLL, where the calibration value generator is configured to: (i) sense an error between the actual output of the ADPLL and the model output, and (ii) generate a calibration value based on the error between the actual output of the ADPLL and the model output to adjust a feedforward gain of the ADPLL.

According to yet another aspect, an apparatus includes: (i) means for obtaining a model of an All-Digital Phase Locked Loop (ADPLL); (ii) means for applying an input signal to the ADPLL to generate an actual output of the ADPLL; (iii) means for applying the input signal to the model to generate a model output; (iv) means for sensing an error between the actual output of the ADPLL and the model output; (v) means for generating a calibration value based on the error between the actual output of the ADPLL and the model output; and (vi) means for adjusting a feedforward gain of the ADPLL based on the calibration value.

According to still another aspect, a non-transitory computer-readable medium includes program code stored thereon for calibrating an All-Digital Phase Locked Loop (ADPLL). The program code includes instructions to direct the apparatus to: (i) obtain a model of the ADPLL; (ii) apply an input signal to the ADPLL to generate an actual output of the ADPLL; (iii) apply the input signal to the model to generate a model output; (iv) sense an error between the actual output of the ADPLL and the model output; (v) generate a calibration value based on the error between the actual output of the ADPLL and the model output; and (vi) adjust a feedforward gain of the ADPLL based on the calibration value.

### BRIEF DESCRIPTION OF THE DRAWINGS

The accompanying drawings are presented to aid in the description of embodiments of the invention and are provided solely for illustration of the embodiments and not limitation thereof.

FIG. 1 illustrates an example of conventional direct modulation of an All-Digital Phase Locked Loop (ADPLL).

FIG. 2 illustrates an apparatus for a model-based calibration of an All-Digital Phase Locked Loop (ADPLL), according to aspects of the disclosure.

FIG. 3 illustrates an example model for use in the model-based calibration of an ADPLL, according to aspects of the disclosure.

FIG. 4 illustrates another example model for use in the model-based calibration of an ADPLL, according to aspects of the disclosure.

FIG. 5 illustrates an example calibration value generator for use in the model-based calibration of an ADPLL, according to aspects of the disclosure.

FIG. 6 illustrates an example wireless transceiver implemented with the model-based calibration of an ADPLL, according to aspects of the disclosure.

FIG. 7 illustrates example wireless devices, according to aspects of the disclosure.

FIG. 8 illustrates an example process of calibrating an ADPLL, according to aspects of the disclosure.

FIG. 9 illustrates sample aspects of components that may be employed in an apparatus configured to support the calibration of an ADPLL, according to aspects of the disclosure.

### DETAILED DESCRIPTION

Various aspects are disclosed in the following description and related drawings directed to specific aspects of the invention. Alternate embodiments may be devised without departing from the scope of the invention. Additionally, well-known elements of the invention will not be described in detail or will be omitted so as not to obscure the relevant details of the invention.

The word “exemplary” is used herein to mean “serving as an example, instance, or illustration.” Any embodiment described herein as “exemplary” is not necessarily to be construed as preferred or advantageous over other embodiments. Likewise, the term “embodiments of the invention” does not require that all embodiments of the invention include the discussed feature, advantage or mode of operation.

The terminology used herein is for the purpose of describing particular embodiments only and is not intended to be limiting of embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Further, many embodiments are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of non-transitory computer readable storage medium having stored therein a corresponding set of computer instructions that upon execution would cause an associated processor to perform the functionality described herein. Thus, the various aspects of the invention may be embodied in a number of different forms, all of which have been contemplated to be within the scope of the claimed subject matter.

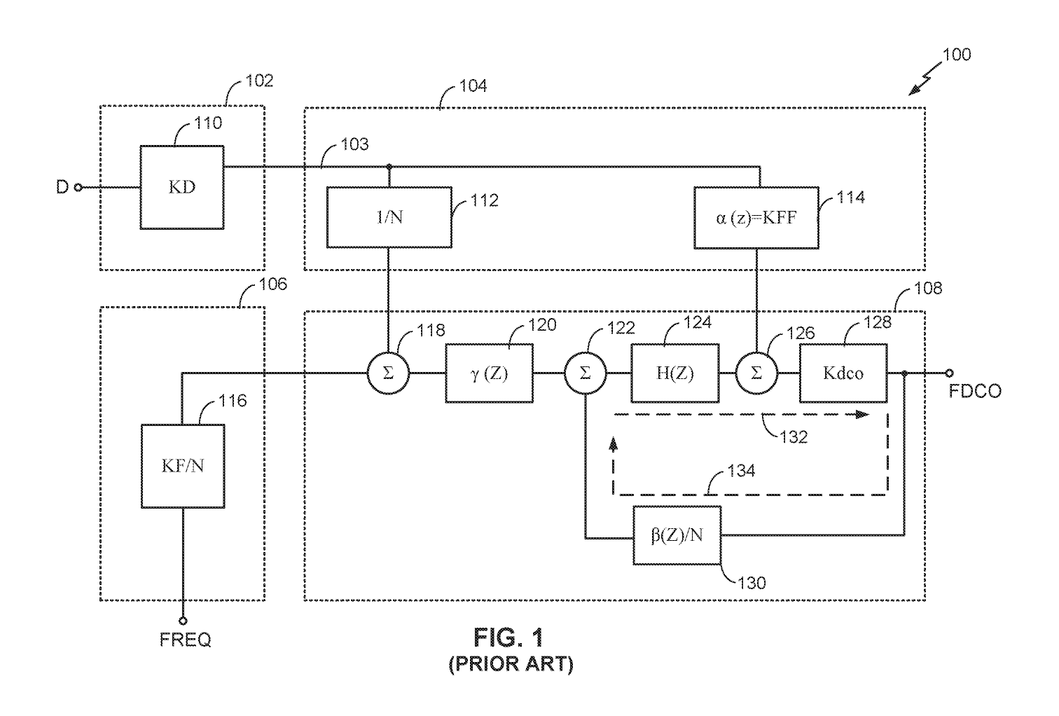

FIG. 1 illustrates an example of conventional direct modulation of an All-Digital Phase Locked Loop (ADPLL) 108. An apparatus 100, of FIG. 1, is illustrated as including a digital scaling block 102, a modulator 104, a frequency scaling block 106, and the ADPLL 108. A feedforward path 132 of the ADPLL 108 includes a digital filter 124 that outputs a stream of digital tuning words. A digitally controlled oscillator (i.e., kdco 128) receives the digital tuning words and outputs a corresponding signal FDCO whose frequency is determined by the digital tuning word. A feedback path 134 includes a block 130, which may include a Time-to-Digital Converter (TDC) or a phase-to-digital converter (PDC) and combined with a frequency divider N. Block 130 receives the FDCO signal and outputs a fractional part of a phase error word. The phase error word is indicative of a phase error between the frequency signal FREQ (scaled by scaling factor KF 116) and the FDCO signal. An accumulator 118 outputs an integer portion of the phase error word. A summer 122 sums corresponding integer portions and fractional portions to output a stream of digital phase error words. The stream of digital phase error words is supplied to the digital filter 124. When the loop is locked, the frequency and/or phase of FDCO is locked to the corresponding frequency and/or phase of the reference clock signal FREQ. In one aspect, when the loop is locked, the frequency and/or phase of FDCO is locked to the corresponding frequency and/or phase of a linear combination of FREQ and digital data D (e.g., KF*FREQ+KD*D=FDCO).

Also illustrated in FIG. 1, is the modulation of digital data D onto the FDCO signal by way of modulator 104. Digital scaling block 102 receives the digital data D and applies a digital scaling factor KD to the digital data to generate an input signal 103. The input signal 103 is representative of an amount to deviate an output frequency of the FDCO signal. As shown in FIG. 1, modulator 104 is coupled to apply the input signal 103 at two points within ADPLL 108. First, N-divider 112 divides the input signal 103 and applies the divided input signal to accumulator 118. Second, feedforward modulation filter 114 applies a step response calibration factor KFF to summer 126 to adjust a feedforward gain of the feedforward path 132 of ADPLL 108. Typically, the step response calibration factor KFF that is applied by feedforward modulation filter 114 is fixed. However, as mentioned above, conventional ADPLLs, such as ADPLL 108 may drift out of calibration during operation with temperature or other process-related conditional changes. Thus, the calibration factors KFF applied by feedforward modulation filter 114 may be inaccurate. Furthermore, the calibration factor KFF applied by feedforward modulation filter 114 may not be accurate when implemented in a transceiver for use in wireless communications, as the transceiver may be required to generate numerous frequencies (e.g., determined by FREF signal), where each operating frequency may require a separate calibration factor.

Accordingly, aspects of the present disclosure provide a method and apparatus for a model-based calibration of an ADPLL. As will be discussed in more detail below, aspects of the present disclosure may utilize an idealized model of the modulated ADPLL in order to dynamically generate a calibration value that adjusts a feedforward gain of the ADPLL to correct for variations that may occur in the feedforward path. In some examples, the model-based calibration of the ADPLL allows calibration at all times (e.g., as a background calibration), even while the ADPLL is transmitting data. Even still, in some aspects, the model-based calibration of the ADPLL may allow arbitrary selection of a loop bandwidth. For example, a low bandwidth may be selected (e.g., lower than dictated by the modulation), where the model-based calibration then provides for the correct modulation even with the lower bandwidth.

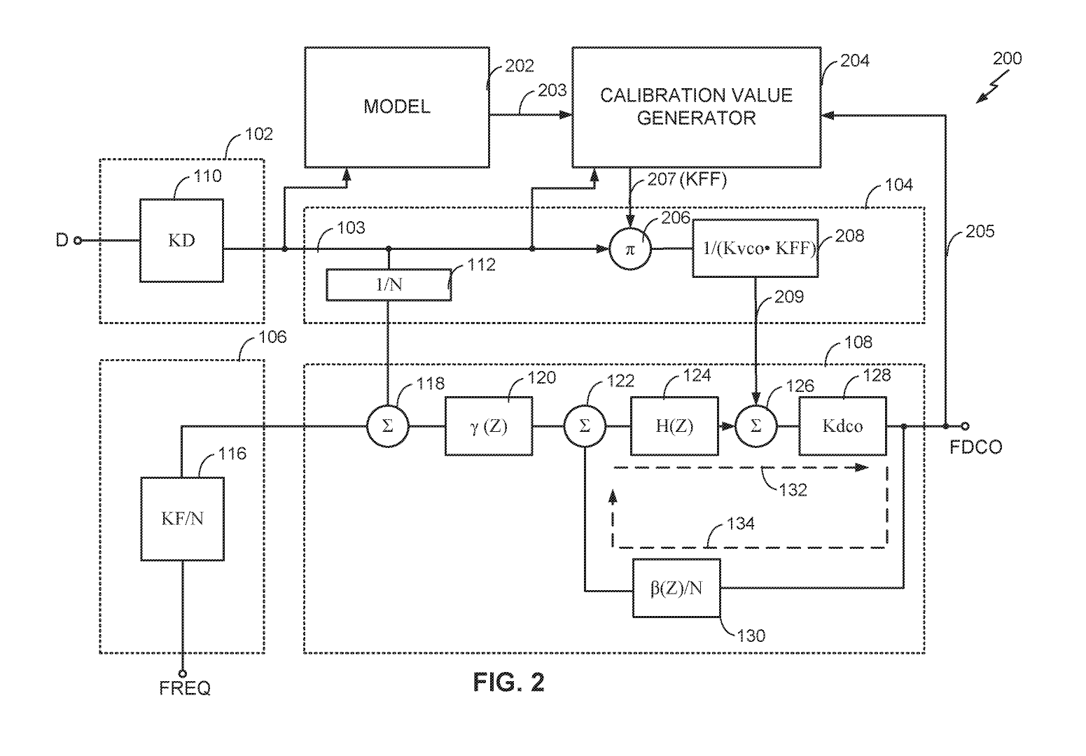

FIG. 2 illustrates an example apparatus 200 for a model-based calibration of an All-Digital Phase Locked Loop (ADPLL) 108, according to aspects of the disclosure. As shown in FIG. 2, apparatus 200 includes a digital scaling block 102, a modulator 104, a frequency scaling block 106, ADPLL 108, model 202, and calibration value generator 204.

In one example, model 202 is an idealized mathematical model of the ADPLL 108. Model 202 may be implemented in hardware (e.g., application specific integrated circuit (ASIC), programmable gate array (PGA), discrete digital circuits, etc.) or in a combination of hardware and software (e.g., a software model executed by a corresponding processor). In certain aspects, the model 202 includes duplicates of one or more components used in the implementation of ADPLL 108. For example, model 202 may include an exact copy of the digital filter 124 included in ADPLL 108. That is, if digital filter 124 is implemented in ADPLL 108 as a software module then the same software module may be duplicated in the implementation of model 202. Similarly, if one or more components of the ADPLL 108 are implemented by way of a PGA, or a series of logic gates, a duplicate PGA or duplicate logic gates may be used to implement corresponding components within the model 202.

In operation, model 202 receives the same input signal 103 (i.e., digital data representative of an amount to deviate the output frequency of the actual output 205 (FDCO) of the ADPLL 108) as applied to the ADPLL 108 via modulator 104. In response to the input signal 103, model 202 generates a model output 203. The model output 203 represents an idealized output of the ADPLL 108 (e.g., based on a mathematical model of the ADPLL 108). The model output 203 is then provided to calibration value generator 204, which senses an error between the actual output 205 and the model output 203. In one example, the error is representative of a difference in frequency between the actual output 205 and the model output 203. In another example, the error is representative of a difference in phase between the actual output 205 and the model output 203. In yet another example, the error is representative of a difference in a combination of frequency and phase. The calibration value generator 204 then generates a calibration value 207, which is provided to modulator 104. As will be discussed in more detail below, the calibration value 207 may be dynamically determined to reduce or otherwise eliminate the sensed error between the model output 203 and the actual output 205.

In the illustrated example of FIG. 2, the calibration value 207 is combined with the input signal 103 by combiner 206 which is provided to block 208 to generate a gain adjustment signal 209. Gain adjustment signal 209 is then provided to summer 126, which adjusts the feedforward gain of feedforward path 132 by adjusting the output of digital filter 124. In one aspect, the gain adjuster block 208 is set to 1/(P[Kdco]·KF) where P[Kdco] is a parameter representing a value close to the gain of the oscillator Kdco 128. In some instances, the exact gain of the oscillator 128 may be unknown and/or be highly susceptible to variations due to temperature. Accordingly, the gain adjustment signal 209 generated by calibration value generator 204 may allow for the compensation for variations in the feedforward path 132 that may be caused by the unknown gain of the oscillator 128. The calibration value 207 is referred to as the KFF value in FIG. 1. When calibrated, calibration value generator 204 adjusts KFF such that KFF/P[Kdco]=1/Kdco.

Furthermore, in some implementations, the gain of the feedforward path 132 may be data dependent. That is, the gain of the feedforward path 132 may depend, in part, on the logic states of the digital data D, represented by input signal 103. Accordingly, in some examples, the calibration value generator 204 may be further configured to receive the input signal 103, where the calibration value 207 is determined in part, based on the logic state of the digital data D. The calibration value generator 204 may adjust the determined calibration value 207 in response to the input signal 103, where the adjusted calibration value is then used to adjust the feedforward gain of the ADPLL 108. For example, calibration value generator 204 may be configured to generate a first calibration value in response to the digital data D being in a first logic state (e.g., logic “0”), where the first calibration value is output as calibration value 207 to adjust the feedforward gain of feedforward path 132 when the digital data is in the first logic state. If the digital data D is in a second logic state (e.g., logic “1”), a second (i.e., different) calibration value is output as the calibration value 207 to adjust the feedforward gain when the digital data is in the second logic state.

In some aspects, calibration value generator 204 may be configured to only generate a new calibration value 207 when a transition of the digital data D between logic states is detected. For example, calibration value generator 204 may be configured to detect a transition of the digital data D from a first logic state to a second logic state in response to the input signal 103. Upon detecting the transition, calibration value generator 204 generates a new calibration value 207 based on the sensed error between the model output 203 and the actual output 205. However, if no transition of the digital data D is detected (i.e., an absence of a transition is detected), then calibration value generator 204 may output a previously generated calibration value 207 (e.g., a calibration value determined in response to a previously sensed error between the actual output 205 and the model output 203). By way of example, the calibration value generator 204 may be configured to generate a first calibration value (i.e., calibration value 207) based at least on the model output 203 and the actual output 205 when the digital data D is in a first logic state (e.g., “0”). If the next bit of the digital data D is the same logic state (e.g., “0”) then no transition of the digital data D has occurred and the calibration value generator 204 may continue generating the previously determined first calibration value. If however, the next bit of the digital data D is a second logic state (e.g., “1”) then a transition of the digital data D has occurred and the calibration value generator 204 may generate a second calibration value that is based on the current outputs of model output 203 and actual output 205.

Thus, in some examples, the value of KFF may be dependent on the input signal 103 so the logic state (u) and the corresponding KFF can have many states (i.e., KFF=KFF(u)). That is, KFF(u)=adapt(q,u) where q is a set of parameters to be adapted and the adaptation of KFF may include the use of a multidimensional adaptation loop. Thus, in certain aspects, the adaptation of KFF may change since both the adapt function listed above and the parameters q can be changed.

What follows is an example illustrating a modification of the update function of the adaptation algorithm that includes updating KFF based on the whole range of logic states in (u) (i.e., logic states of input signal 103). In this example, the calibrated KFF is dependent on the logic state (u), but where only two logic states, u0 and u1, may be used for adaptation with one adaptation loop:

KFF(u)=f0(u)*KFF(u0)+f1(u)*KFF(u1)=function(KFF(u0),KFF(u1),f0,f1,u)

Here, a linear interpolation is performed between two calibrated states with weighting factors f0(u) and f1(u): f0(u)+f1(u)=1. One function here is f0(u)=1−a(u) and f1(u)=a(u), where a(u)=(u−u0)/(u1−u0) normalize the range of a to be between 0 and 1. The adaptation performed by calibration value generator 204 may provide an update of DKFF(u)=DKFF in terms of DKFF(u0) and DKFF(u1):

DKFF(u)=f0(u)*DKFF(u0)+f1(u)*DKFF(u1) EQ. 1

One example update is as follows:

DKFF(u0)=f0(u)*DKFF/(f0(u)*f0(u)+f1(u)*f1(u)) EQ. 2

DKFF(u1)=f1(u)*DKFF/(f0(u)*f0(u)+f1(u)*f1(u)) EQ. 3

The two calibrated states are updated as KFF(u0)=1+DKFF(u0) and KFF(u1)=1+DKFF(u1).

Thus, calibration value generator 204 may estimate and provide two KFF calibrated values (one for state u0, and another for state u1) and interpolate KFF to estimate the rest of the states KFF(u). Other examples may include a more advanced and complete adaptation loop that could produce an estimate of KFF(u) (e.g., if KFF(u) is not linear).

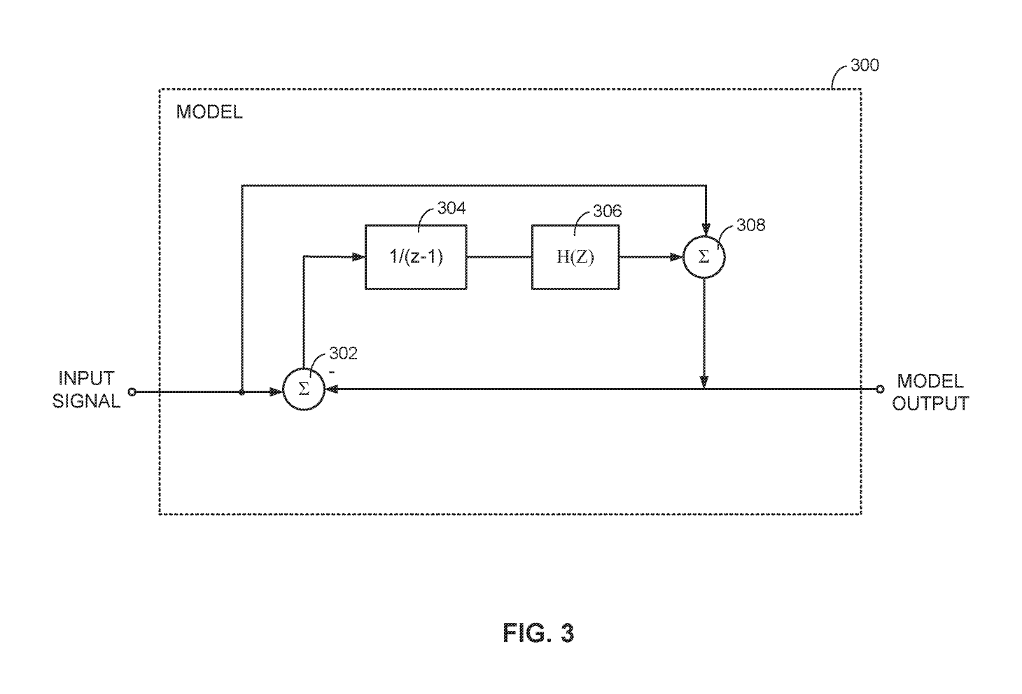

FIG. 3 illustrates an example model 300 for use in the model-based calibration of an ADPLL, according to aspects of the disclosure. Model 300 is one possible implementation of model 202 of FIG. 2. The illustrated example of model 300 includes a summer 302, an integrator 304, a digital filter 306, and a summer 308. In one example, digital filter 306 is an exact duplicate of digital filter 124 utilized in ADPLL 108. Model 300 is coupled to receive an input signal (e.g., input signal 103) that is representative of an amount to deviate an output frequency of an output of the ADPLL (e.g., actual output 205 of ADPLL 108). The input signal is provided to summer 302 and to summer 308. The output of summer 308 is provided as feedback to summer 302, which provides a difference signal to integrator 304. Digital filter 306 is implemented as a loop filter and filters the output of integrator 304. As mentioned above, the model output of model 300 may represent an idealized output of an ADPLL (e.g., ADPLL 108). In one example, the model 300 is invariant to changes in feedforward gain that may affect the feedforward gain of ADPLL 108 (e.g., variations in gain of the oscillator 128 due to temperature changes).

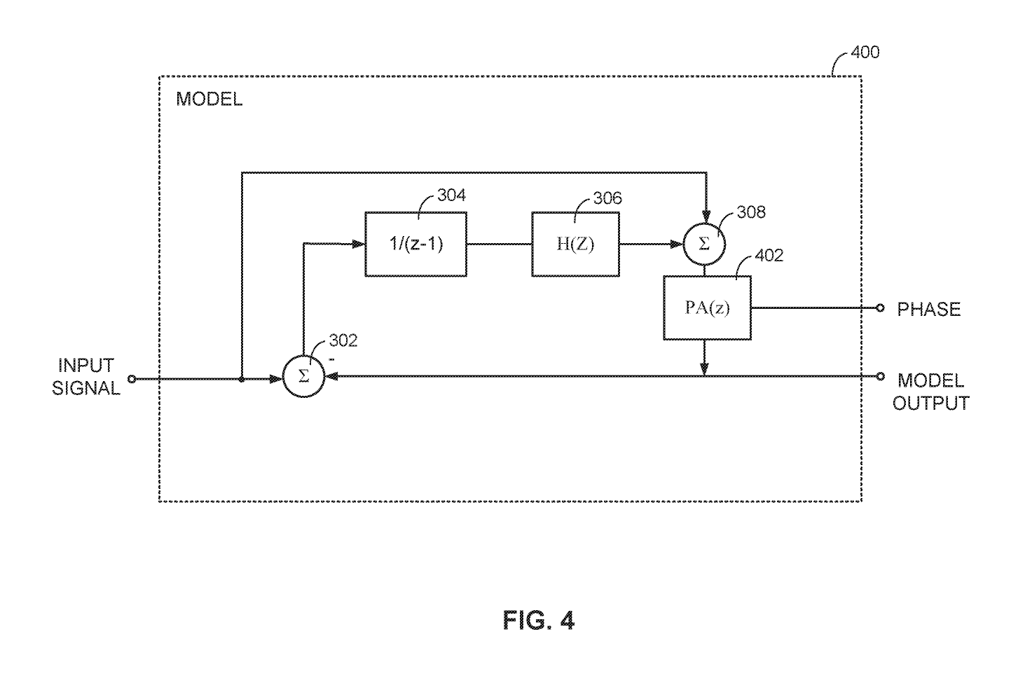

FIG. 4 illustrates another example model 400 for use in the model-based calibration of an ADPLL, according to aspects of the disclosure. Model 400 is one possible implementation of model 202 of FIG. 2. Model 400 is similar to model 300 of FIG. 3, but includes an additional phase estimation block 402. Phase estimation block 402 is configured to estimate a phase shift of an oscillator (e.g., oscillator 128) included in the ADPLL in response to a PHASE signal. In some aspects, the oscillator 128 of ADPLL 108 may experience significant phase shift due to power amplifier (PA) pulling of the oscillator 128 and/or due to other memory effects of the oscillator 128. Accordingly, the phase estimation block 402 may receive the PHASE signal that is representative of the phase shift and adds a delay to the model output to reduce the effects of such a phase shift.

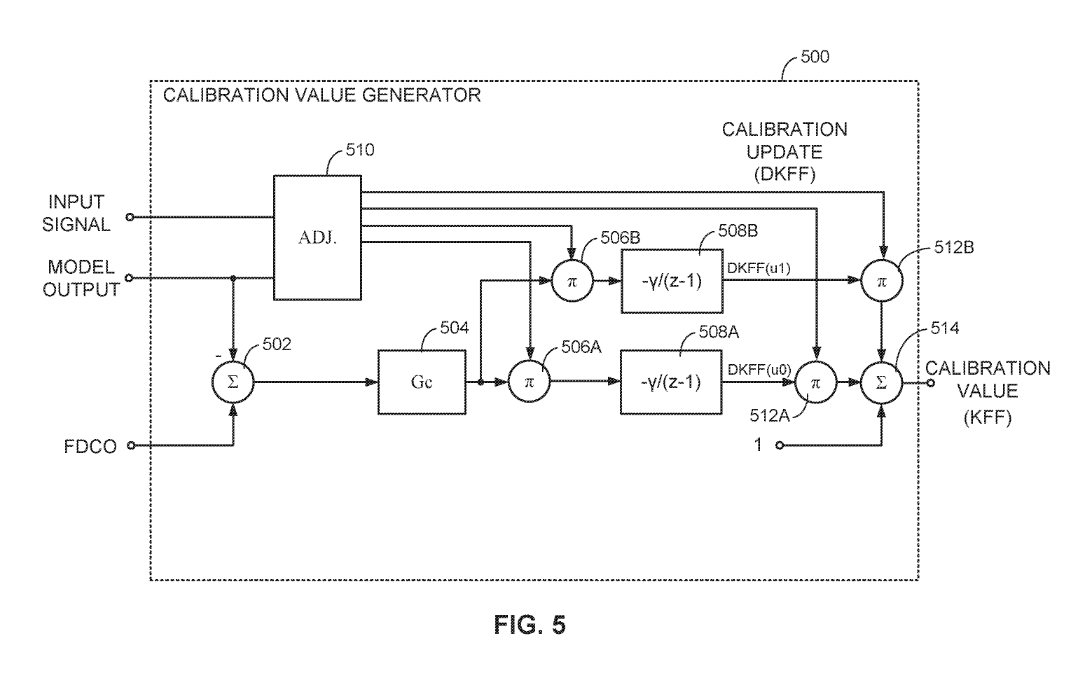

FIG. 5 illustrates an example calibration value generator 500 for use in the model-based calibration of an ADPLL, according to aspects of the disclosure. Calibration value generator 500 is one possible implementation of calibration value generator 204 of FIG. 2. The illustrated example of calibration value generator 500 includes a summer 502, a gain block 504, summers 506A and 506B, and an integrators 508A and 508B, an adjustment block 510, summers 512A and 512B, and a summation block 514. As shown in FIG. 5, calibration value generator 500 is coupled to receive an input signal (e.g., input signal 103), a model output (e.g., model output 203), and an FDCO output signal (e.g., actual output 205).

In operation, summer 502 is configured to sense an error between the model output and the FDCO output signal. The error output of summer 502 is then provided to gain block 504, which provides an amplified error signal to summers 506A and 506B. The output of summers 506A and 506B are then provided to integrators 508A and 508B, respectively, to generate a respective updated calibration value (e.g., DKFF(u0) and DKFF(u1). As shown in FIG. 5, calibration value generator 500 includes an adjustment block 510 that is configured to generate an adjustment to the calibration value based on the input signal. Thus, in one aspect, the generation of the calibration value may be data dependent. As discussed above, the calibration value generator 500 may generate different calibration values, in part, based on the logic state of the digital data D. Thus, adjustment block 510 may detect the logic state of the digital data D based on the input signal and generate an adjustment to be applied to the generation of the calibration value via summers 506A, 506B, 512A, and 512B. Summation block 514 is configured to sum the outputs of integrators 508A and 508B with a value of one (“1”) to properly output the calibration value KFF. In one example, the calibration value generator 500 of FIG. 5 is configured to implement equations 1 and 2, listed above, in the generation of the calibration value KFF.

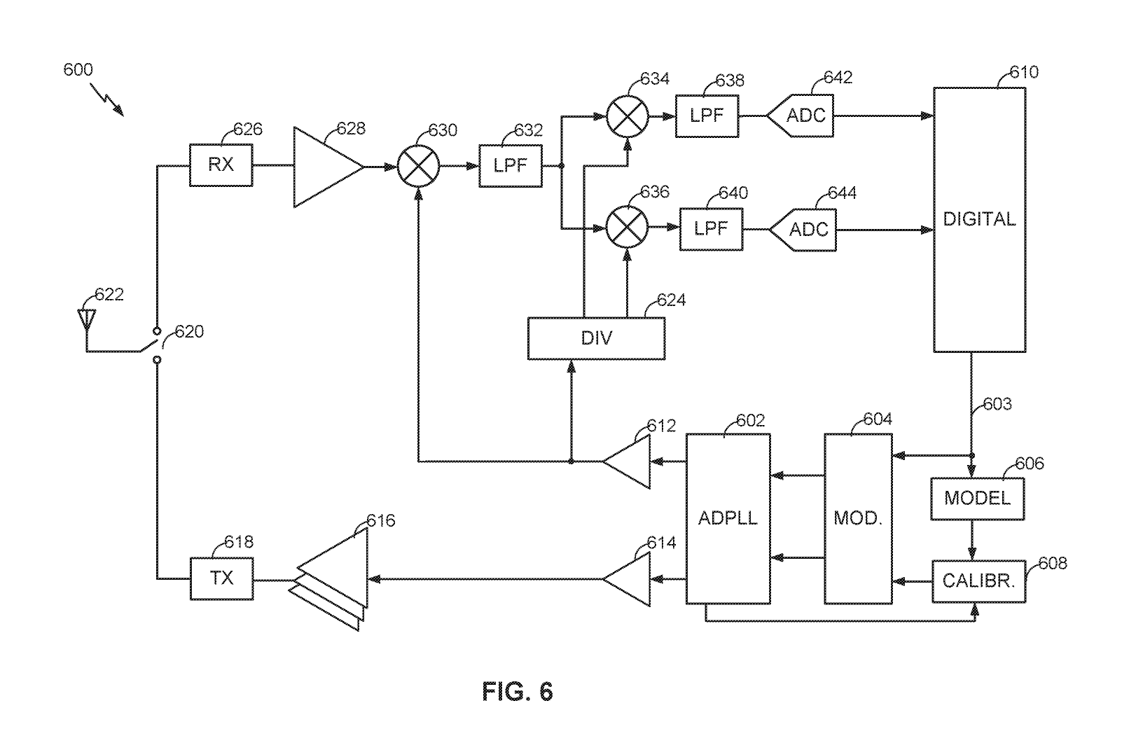

FIG. 6 illustrates an example wireless transceiver 600 implemented with the model-based calibration of an ADPLL 602, according to aspects of the disclosure. The illustrated example of wireless transceiver 600 includes ADPLL 602, a modulator 604, a model 606, a calibration value generator 608, a digital controller 610, buffers 612 and 614, transmit amplifiers 616, a transmit matching network 618, a transmit/receive switch 620, an antenna 622, a divider 624, a receive matching network 626, a front end amplifier 628, a mixer 630, a low pass filter 632, mixers 634 and 636, low pass filters 638 and 640, and analog-to-digital converters (ADCs) 642 and 644.

The wireless transceiver 600 is illustrated as having distinct transmit and receive processing paths. Although FIG. 6 illustrates the transmit and receive processing paths as sharing the same ADPLL 602, other implementations of wireless transceivers may implement and utilize a separate ADPLL for each transmit and receive paths.

The antenna 622 can be shared by both transmit and receive processing paths.

The antenna 622 couples received wireless signals to transmit/receive switch 620 (also referred to as a duplexer) that can be configured to couple the receive signals from the antenna 622 to the remainder of the receive operating path while isolating the receive path from transmit signals. The receive output from the transmit/receive switch 620 is coupled to receive matching network 626 which is coupled to front end amplifier 628, which can be, for example, a low noise amplifier (LNA). The front end amplifier 628 typically operates to substantially govern the total receiver noise figure, and thus, is typically implemented as an LNA having 10-20 dB of gain. The output from the front end amplifier 628 is coupled to mixer 630 which is coupled to a low pass filter 632.

The low pass filter 632 operates to perform RF selection by eliminating or otherwise attenuating signals outside a desired receive RF operating band. The low pass filter 632 can, for example, contribute to adjacent channel rejection. The output from the low pass filter 632 can be coupled to an RF input of a frequency converter, here depicted as mixers 634 and 636. The second inputs to the mixers 634 and 636 are driven by divider 624, which is driven by a local oscillator signal that is generated by ADPLL 602. The ADPLL 602 may be substantially or wholly implemented within wireless transceiver 600.

The output from the low pass filters 638 and 640 can be baseband signals that are coupled to respective ADCs 642 and 644 that operate to generate a digital representation of the respective baseband signals. The digital baseband signals are coupled to be received at an input of the digital controller 610. In one example, the digital controller 610 is a baseband processor configured to further process the received digital baseband signals.

The ADPLL 602 may be configured to operate in conjunction with a first frequency reference (not shown) to generate one or more oscillator signals. The one or more oscillator signals can be used as a local oscillator for the received frequency translation operation via receive buffer 612 and/or for transmit operations via transmit buffer 614. As shown in FIG. 6, an oscillator signal output from the ADPLL 602 can be coupled to an input of mixer 630 as well as to an input to divider 624.

The receiver embodiment illustrated in FIG. 6 implements a direct conversion technique in which the receive RF signal is converted to baseband in a single frequency conversion stage. Of course, the receiver in the wireless transceiver 600 is not limited to any particular configuration and may utilize direct conversion, super heterodyne, or some other configuration.

As shown in FIG. 6, the wireless transceiver 600 also includes a complementary transmitter. The digital controller 610 is configured to generate an input signal 603 representing data for transmission. The modulator 604 can be configured to directly modulate the digital data onto the output signal of ADPLL 602. Calibration of the ADPLL 602 may be performed during transmit operations of the wireless transceiver 600 by way of model 606 and calibration value generator 608. ADPLL 602 may be implemented by way of any of the aforementioned ADPLLs including ADPLL 108 of FIG. 2. Modulator 604 may be implemented by way of any of the aforementioned modulators including modulator 104 of FIG. 2. Model 606 may be implemented by way of any of the aforementioned models including model 202 of FIG. 2, model 300 of FIG. 3, or model 400 of FIG. 4. Calibration value generator 608 may be implemented by way of any of the aforementioned calibration value generators including calibration value generator 204 of FIG. 2 or calibration value generator 500 of FIG. 5.

The output from the transmit buffer 614 can be coupled to a transmit amplifier 616 that may alternatively be referred to as a power amplifier (PA). The transmit amplifier 616 can have a variable gain or a variable gain stage and can be configured to amplify the modulated second oscillator signal to a desired transmit power level. The output from the transmit amplifier 616 is coupled to a transmit input of the transmit/receive switch 620 where it is coupled to the antenna 622.

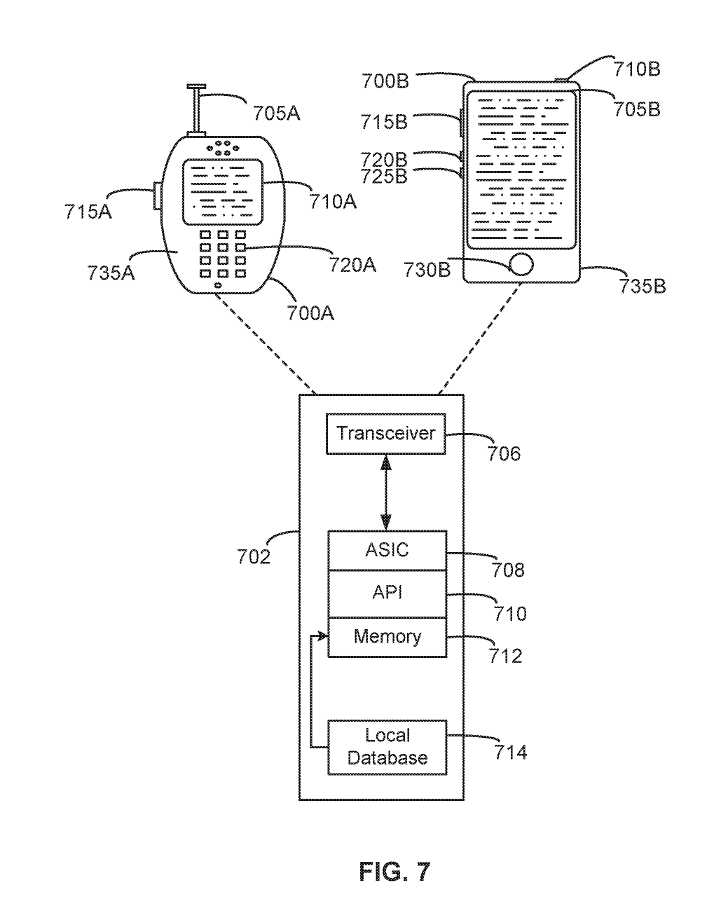

FIG. 7 illustrates example wireless devices 700A and 700B, according to aspects of the disclosure. In some examples, wireless devices 700A and 700B may herein be referred to as wireless mobile stations. The example wireless device 700A is illustrated in FIG. 7 as a calling telephone and wireless device 700B is illustrated as a touchscreen device (e.g., a smart phone, a tablet computer, etc.). As shown in FIG. 7, an exterior housing 735A of wireless device 700A is configured with an antenna 705A, a display 710A, at least one button 715A (e.g., a PTT button, a power button, a volume control button, etc.) and a keypad 720A among other components, not shown in FIG. 7 for clarity. An exterior housing 735B of wireless device 700B is configured with a touchscreen display 705B, peripheral buttons 710B, 715B, 720B and 725B (e.g., a power control button, a volume or vibrate control button, an airplane mode toggle button, etc.), at least one front-panel button 730B (e.g., a Home button, etc.), among other components, not shown in FIG. 7 for clarity. For example, while not shown explicitly as part of wireless device 700B, the wireless device 700B may include one or more external antennas and/or one or more integrated antennas that are built into the exterior housing 735B of wireless device 700B, including but not limited to WiFi antennas, cellular antennas, satellite position system (SPS) antennas (e.g., global positioning system (GPS) antennas), and so on.

While internal components of wireless devices such as the wireless devices 700A and 700B can be embodied with different hardware configurations, a basic high-level configuration for internal hardware components is shown as platform 702 in FIG. 7. The platform 702 can receive and execute software applications, data and/or commands transmitted from a radio access network (RAN) that may ultimately come from a core network, the Internet and/or other remote servers and networks (e.g., an application server, web URLs, etc.). The platform 702 can also independently execute locally stored applications without RAN interaction. The platform 702 can include a transceiver 706 operably coupled to an application specific integrated circuit (ASIC) 708, or other processor, microprocessor, logic circuit, or other data processing device. The ASIC 708 or other processor executes the application programming interface (API) 710 layer that interfaces with any resident programs in the memory 712 of the electronic device. The memory 712 can be comprised of read-only or random-access memory (RAM and ROM), EEPROM, flash cards, or any memory common to computer platforms. The platform 702 also can include a local database 714 that can store applications not actively used in memory 712, as well as other data. The local database 714 is typically a flash memory cell, but can be any secondary storage device as known in the art, such as magnetic media, EEPROM, optical media, tape, soft or hard disk, or the like.

In one aspect, wireless communications by wireless devices 700A and 700B may be enabled by transceiver 706 based on different technologies, such as CDMA, W-CDMA, time division multiple access (TDMA), frequency division multiple access (FDMA), Orthogonal Frequency Division Multiplexing (OFDM), GSM, 2G, 3G, 4G, LTE, or other protocols that may be used in a wireless communications network or a data communications network. Voice transmission and/or data can be transmitted to the electronic devices from a RAN using a variety of networks and configurations. Accordingly, the illustrations provided herein are not intended to limit the embodiments of the invention and are merely to aid in the description of aspects of embodiments of the invention.

Accordingly, aspects of the present disclosure can include a wireless device (e.g., wireless device 700A, 700B, etc.) configured, and including the ability to perform the functions as described herein. For example, transceiver 706 may be implemented as wireless transceiver 600 of FIG. 6, including ADPLL 602, modulator 604, model 606, and calibration value generator 608. As will be appreciated by those skilled in the art, the various logic elements can be embodied in discrete elements, software modules executed on a processor or any combination of software and hardware to achieve the functionality disclosed herein. For example, ASIC 708, memory 712, API 710 and local database 714 may all be used cooperatively to load, store and execute the various functions disclosed herein and thus the logic to perform these functions may be distributed over various elements. In one example, the model 606 is provided as a software module stored and executed from memory 712. In another example, model 606 is implemented as one or more digital components implemented by way of ASIC 708. Alternatively, the functionality could be incorporated into one discrete component. Therefore, the features of the wireless devices 700A and 700B in FIG. 7 are to be considered merely illustrative and the invention is not limited to the illustrated features or arrangement.

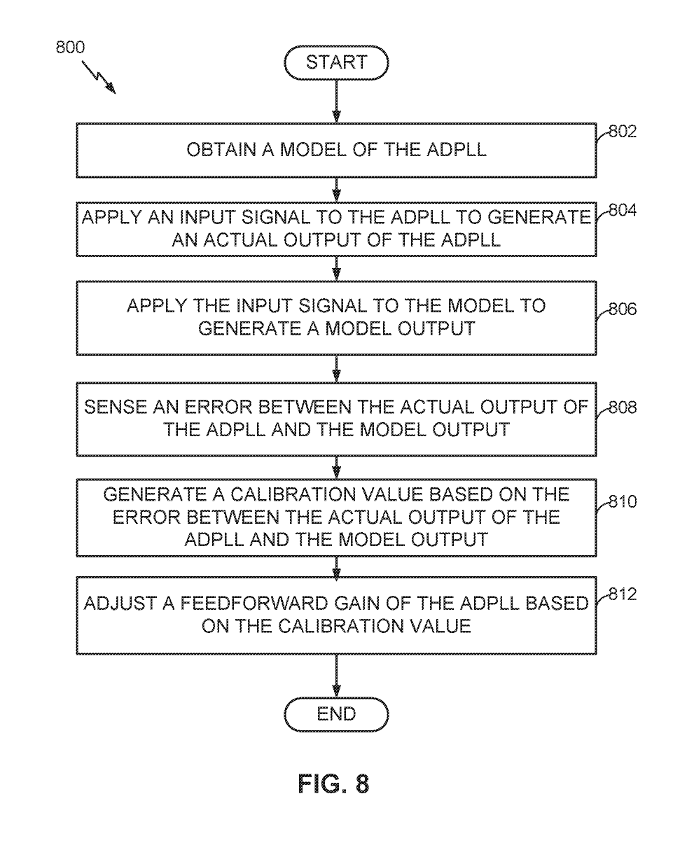

FIG. 8 illustrates an example process 800 of calibrating an ADPLL, according to aspects of the disclosure. Process 800 will be described with reference to at least FIGS. 2 and 8. In a process block 802, apparatus 200 obtains a model 202 of the ADPLL 108. If model 202 is implemented as a software module, obtaining model 202 may include retrieving the model from memory (e.g., memory 712 of FIG. 7). If model 202 is implemented as one or more digital circuits, obtaining model 202 may include activating or otherwise accessing the digital circuits.

Next, process block 804 includes applying an input signal to the ADPLL to generate an actual output of the ADPLL. By way of example, FIG. 2 illustrates input signal 103 applied to the ADPLL 108 by way of modulator 104, where ADPLL 108 generates the actual output 205 in response thereto.

Process block 806 includes applying the input signal to the model to generate a model output. Again, by way of example, FIG. 2 illustrates input signal 103 applied to the model 202, where model 202 generates a model output 203 in response thereto.

In a process block 808, a calibration value generator (e.g., 204) senses an error between the actual output of the ADPLL and the model output. Next, in process block 810, calibration value generator (e.g., 204) generates a calibration value (e.g., 207) based on the error between the actual output of the ADPLL and the model output. In a process block 812, the feedforward gain of the ADPLL is adjusted based on the calibration value. For example, as shown in FIG. 2, the modulator 104 is configured to generate a gain adjustment signal 209 to adjust the feedforward gain of feedforward path 132 based on the calibration value 207.

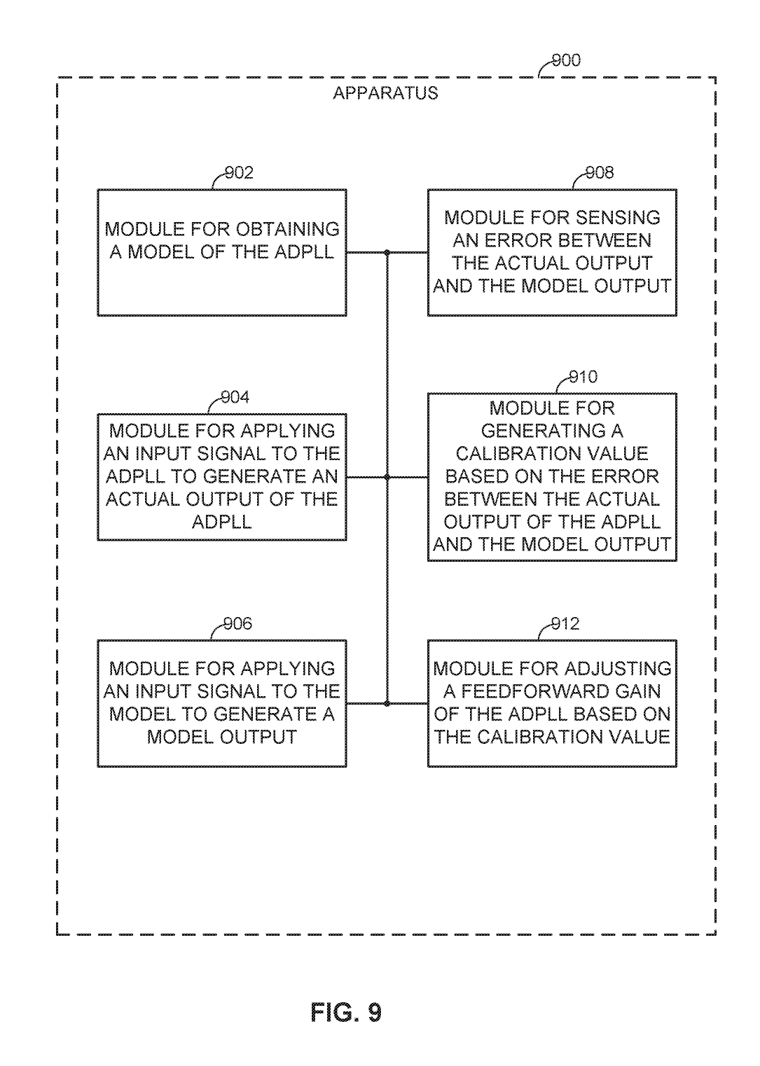

FIG. 9 illustrates sample aspects of components that may be employed in an apparatus 900 configured to support the calibration of an ADPLL, according to aspects of the disclosure. Apparatus 900 is one possible implementation of apparatus 200 of FIG. 2.

A module 902 for obtaining a model of an ADPLL may correspond at least in some aspects to, for example, model 202 of FIG. 2, model 300 of FIG. 3, model 400 of FIG. 4, model 606 of FIG. 6, a memory 712 of FIG. 7, and/or digital controller 610 of FIG. 6. A module 904 for applying an input signal to the ADPLL to generate an actual output of the ADPLL may correspond at least in some aspects to, for example, ADPLL 108 of FIG. 2 and/or ADPLL 602 of FIG. 6. A module 906 for applying the input signal to the model to generate a model output may correspond at least in some aspects to, for example, model 202 of FIG. 2, model 300 of FIG. 3, model 400 of FIG. 4, model 606 of FIG. 6, a memory 712 of FIG. 7, and/or digital controller 610 of FIG. 6. A module 908 for sensing an error between the actual output and the model output may correspond at least in some aspects to, for example, calibration value generator 204 of FIG. 2, calibration value generator 500 of FIG. 5, and/or calibration value generator 608 of FIG. 6. A module 910 for generating a calibration value based on the error between the actual output of the ADPLL and the model output may correspond at least in some aspects to, for example, calibration value generator 204 of FIG. 2, calibration value generator 500 of FIG. 5, and/or calibration value generator 608 of FIG. 6. A module 912 for adjusting a feedforward gain of the ADPLL based on the calibration value may correspond at least in some aspects to, for example, modulator 104 of FIG. 2, and/or modulator 604 of FIG. 6.

The functionality of the modules 902-912 may be implemented in various ways consistent with the teachings herein. In some designs, the functionality of modules 902-912 may be implemented as one or more electrical components. In some designs, the functionality of modules 902-912 may be implemented as a processing system including one or more processor components. In some designs, the functionality of modules 902-912 may be implemented using, for example, at least a portion of one or more integrated circuits (e.g., an ASIC). As discussed herein, an integrated circuit may include a processor, software, other related components, or some combination thereof. Thus, the functionality of different modules may be implemented, for example, as different subsets of an integrated circuit, as different subsets of a set of software modules, or a combination thereof. Also, it will be appreciated that a given subset (e.g., of an integrated circuit and/or of a set of software modules) may provide at least a portion of the functionality for more than one module.

In addition, the components and functions represented by FIG. 9, as well as other components and functions described herein, may be implemented using any suitable means. Such means also may be implemented, at least in part, using corresponding structure as taught herein. For example, the components described above in conjunction with the “module for” components of FIG. 9 also may correspond to similarly designated “means for” functionality. Thus, in some aspects, one or more of such means may be implemented using one or more of processor components, integrated circuits, or other suitable structure as taught herein.

Further, those of skill in the art will appreciate that the various illustrative logical blocks, modules, circuits, and algorithm steps described in connection with the embodiments disclosed herein may be implemented as electronic hardware or a combination of computer software and electronic hardware. To clearly illustrate this interchangeability of hardware and hardware-software combinations, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

Accordingly, an embodiment of the invention can include a non-transitory computer readable media embodying a method for the model-based calibration of an ADPLL. Accordingly, the invention is not limited to illustrated examples and any means for performing the functionality described herein are included in embodiments of the invention.

While the foregoing disclosure shows illustrative embodiments of the invention, it should be noted that various changes and modifications could be made herein without departing from the scope of the invention as defined by the appended claims. The functions, steps and/or actions of the method claims in accordance with the embodiments of the invention described herein need not be performed in any particular order. Furthermore, although elements of the invention may be described or claimed in the singular, the plural is contemplated unless limitation to the singular is explicitly stated.

1. A method of calibrating, by a computing device, an All-Digital Phase Locked Loop (ADPLL), the method comprising:
obtaining, by the computing device, a model of the ADPLL;
applying an input signal to the ADPLL to generate an actual output of the ADPLL;
applying the input signal to the model to generate a model output;
sensing an error between the actual output of the ADPLL and the model output;
generating a calibration value based on the error between the actual output of the ADPLL and the model output; and
adjusting a feedforward gain of the ADPLL based on the calibration value.

2. The method of claim 1, wherein the model is a mathematical model of the ADPLL.

3. The method of claim 1, wherein the input signal comprises digital data representative of an amount to deviate an output frequency of the actual output of the ADPLL.

4. The method of claim 3, wherein generating the calibration value comprises:
generating a first calibration value in response to the digital data being in a first logic state, wherein adjusting the feedforward gain is based on the first calibration value when the digital data is in the first logic state; and
generating a second calibration value in response to the digital data being in a second logic state, wherein adjusting the feedforward gain is based on the second calibration value when the digital data is in the second logic state.

5. The method of claim 3, further comprising:
detecting a transition of the digital data between a first logic state and a second logic state, wherein adjusting the feedforward gain of the ADPLL is in response to detecting the transition.

6. The method of claim 5, further comprising:
adjusting the feedforward gain of the ADPLL based on a previously generated calibration value in response to detecting an absence of the transition of the digital data between the first logic state and the second logic state.

7. The method of claim 1, further comprising:
adjusting the calibration value in response to the input signal to generate an adjusted calibration value, wherein adjusting the feedforward gain of the ADPLL is based on the adjusted calibration value.

8. The method of claim 1, wherein adjusting the feedforward gain of the ADPLL comprises adjusting an output of a digital filter of the ADPLL.

9. The method of claim 1, wherein applying the input signal to the model to generate the model output comprises estimating a phase shift of an oscillator included in the ADPLL.

10. An apparatus, comprising:
an All-Digital Phase Locked Loop (ADPLL) configured to generate an actual output of the ADPLL in response to an input signal;
a model of the ADPLL configured to receive the input signal and to generate a model output in response to the input signal; and
a calibration value generator coupled to the model and to the ADPLL, wherein the calibration value generator is configured to:
sense an error between the actual output of the ADPLL and the model output, and
generate a calibration value based on the error between the actual output of the ADPLL and the model output to adjust a feedforward gain of the ADPLL.

11. The apparatus of claim 10, wherein the model of the ADPLL is a mathematical model of the ADPLL.

12. The apparatus of claim 10, wherein the input signal comprises digital data representative of an amount to deviate an output frequency of the actual output of the ADPLL.

13. The apparatus of claim 12, wherein the calibration value generator is further configured to:
generate a first calibration value in response to the digital data being in a first logic state, wherein an adjustment to the feedforward gain is based on the first calibration value when the digital data is in the first logic state; and
generate a second calibration value in response to the digital data being in a second logic state, wherein the adjustment to the feedforward gain is based on the second calibration value when the digital data is in the second logic state.

14. The apparatus of claim 12, wherein the calibration value generator is further configured to:
detect a transition of the digital data between a first logic state and a second logic state, wherein the adjustment to the feedforward gain of the ADPLL is in response to detecting the transition.

15. The apparatus of claim 14, wherein the adjustment to the feedforward gain of the ADPLL is based on a previously generated calibration value in response to detecting an absence of the transition of the digital data between the first logic state and the second logic state.

16. The apparatus of claim 10, wherein the calibration value generator is further configured to:
adjust the calibration value in response to the input signal to generate an adjusted calibration value, wherein the adjustment to the feedforward gain of the ADPLL is based on the adjusted calibration value.

17. The apparatus of claim 10, further comprising a modulator configured to receive the calibration value and to adjust an output of a digital filter of the ADPLL based on the calibration value.

18. The apparatus of claim 10, wherein the model is further configured to estimate a phase shift of an oscillator included in the ADPLL.

19. An apparatus, comprising:
means for obtaining a model of an All-Digital Phase Locked Loop (ADPLL);
means for applying an input signal to the ADPLL to generate an actual output of the ADPLL;
means for applying the input signal to the model to generate a model output;
means for sensing an error between the actual output of the ADPLL and the model output;
means for generating a calibration value based on the error between the actual output of the ADPLL and the model output; and
means for adjusting a feedforward gain of the ADPLL based on the calibration value.

20. The apparatus of claim 19, wherein the input signal comprises digital data representative of an amount to deviate an output frequency of the actual output of the ADPLL.

21. The apparatus of claim 20, wherein the means for generating the calibration value comprises:
means for generating a first calibration value in response to the digital data being in a first logic state, wherein the means for adjusting the feedforward gain is based on the first calibration value when the digital data is in the first logic state; and
means for generating a second calibration value in response to the digital data being in a second logic state, wherein the means for adjusting the feedforward gain is based on the second calibration value when the digital data is in the second logic state.

22. The apparatus of claim 20, further comprising:
means for detecting a transition of the digital data between a first logic state and a second logic state, wherein the means for adjusting the feedforward gain of the ADPLL is in response to detecting the transition.

23. The apparatus of claim 22, further comprising:
means for adjusting the feedforward gain of the ADPLL based on a previously generated calibration value in response to detecting an absence of the transition of the digital data between the first logic state and the second logic state.

24. The apparatus of claim 19, further comprising:
means for adjusting the calibration value in response to the input signal to generate an adjusted calibration value, wherein the means for adjusting the feedforward gain of the ADPLL is based on the adjusted calibration value.

25. The apparatus of claim 19, wherein the means for adjusting the feedforward gain of the ADPLL comprises means for adjusting an output of a digital filter of the ADPLL.

26. The apparatus of claim 19, wherein the means for applying the input signal to the model to generate the model output comprises means for estimating a phase shift of an oscillator included in the ADPLL.

27. A non-transitory computer-readable medium including program code stored thereon for calibrating an All-Digital Phase Locked Loop (ADPLL), the program code comprising instructions to direct apparatus to:
obtain a model of the ADPLL;
apply an input signal to the ADPLL to generate an actual output of the ADPLL;
apply the input signal to the model to generate a model output;
sense an error between the actual output of the ADPLL and the model output;
generate a calibration value based on the error between the actual output of the ADPLL and the model output; and
adjust a feedforward gain of the ADPLL based on the calibration value.

28. The non-transitory computer-readable medium of claim 27, wherein the input signal comprises digital data representative of an amount to deviate an output frequency of the actual output of the ADPLL.

29. The non-transitory computer-readable medium of claim 27, further comprising instructions to direct the apparatus to:
adjust the calibration value in response to the input signal to generate an adjusted calibration value, wherein the instructions to adjust the feedforward gain of the ADPLL is based on the adjusted calibration value.

30. The non-transitory computer-readable medium of claim 27, wherein the instructions to apply the input signal to the model to generate the model output comprises instructions to estimate a phase shift of an oscillator included in the ADPLL.
